(19) United States
(12) Patent Application Publication
(10) Pub. No.: US 2025/0252239 A1
(43) Pub. Date: Aug. 7, 2025

(54) QUANTUM CIRCUIT SETUP FOR LATTICE GAS AUTOMATA SIMULATION

(71) Applicant: Quanscient Oy, Tampere (FI)

(72) Inventors: Antonio David Bastida Zamora, Espoo (FI); Ljubomir Budinski, Novi Sad (RS); Ossi Niemimäki, Helsinki (FI); Valtteri Lahtinen, Lempäälä (FI)

(73) Assignee: Quanscient Oy, Tampere (FI)

(21) Appl. No.: 18/433,592

(22) Filed: Feb. 6, 2024

(51) Int. Cl. G06F 30/28; G06N 10/40

(52) U.S. Cl. CPC G06F 30/28; G06N 10/40

(57) ABSTRACT

A quantum circuit for a lattice gas automata simulation includes an initialization step performed by setting up, for the quantum circuit, a position register, a channel register and a first ancilla register. To the position register, the channel register and the first ancilla register are applied in a sequential order:
(i) a collision step constructed using a first set of multi-controlled gates, a second set of multi-controlled gates, and four CX gates arranged between the first set and the second set, the collision step being applied to the channel register and the first ancilla register;
(ii) a mapping step constructed using two Hadamard gates and four multi-controlled SWAP gates, the mapping step being applied to the channel register and the first ancilla register; and
(iii) a propagation step being applied to the position register and the first ancilla register.

### TECHNICAL FIELD

The present disclosure relates to a method of setting up a quantum circuit for a lattice gas automata simulation. The present disclosure also relates to a quantum computer or a quantum emulator that is configured to execute the aforementioned method. The present disclosure further relates to a computer program product having computer program instructions stored thereon, the computer program instructions being executable by at least one processor in a classical computer to control a quantum computer or a quantum emulator to perform the aforementioned method.

### BACKGROUND

Cellular automata have been widely explored in computational physics due to their ability to transform simple micro-dynamical rules into a specific macroscopic behaviour. A type of cellular automaton called lattice gas automaton (LGA) was devised to simulate fluid dynamics effectively; that is, LGA originated from the cellular automaton. The Hardy-Pomeau-Pazzis (HPP) and Frisch-Hasslacher-Pomeau (FHP) models are two-dimensional LGA models. LGA was largely abandoned due to the advantages presented by the lattice Boltzmann methods (LBM; which are a class of models in computational fluid dynamics), specifically the noise resilience (in contrast to the local fluctuations for the LGA) and flexibility in simulating complex multi-physics.

However, with the surge of quantum computing, LGA could be one of the key methods to realize the quantum advantage, as it provides a simple framework for encoding lattice points and can model fluid evolution even in nonlinear models. In recent years, there have been several attempts at bringing the LGA and LBM methods to quantum computing. One of the first attempts to quantize cellular automata and lattice gas automata models has been described in “From quantum cellular automata to quantum lattice gases”, by D. A. Meyer, published in Journal of Statistical Physics 85 (1996) 551-574. Insisting on the exact unitarity of a collision operator to maintain consistency with standard quantum mechanics, Meyer formulated a collision operator for the simplest of one-dimensional quantum cellular automaton and quantum LGA (QLGA) models. To extend the applicability of the QLGA beyond the simulation of quantum systems, in particular to computational fluid dynamics, Yepez derived a lattice Boltzmann equation that exactly describes kinetic transport at a mesoscopic scale in a quantum lattice gas. In other words, Yepez showed that the lattice Boltzmann equation is an exact representation of the particle dynamics, including all the effects due to quantum superposition and entanglement. This has been described in “Quantum lattice-gas model for computational fluid dynamics”, by J. Yepez, published in PHYSICAL REVIEW E 63 (2001) 1-18. This then lead to further work on QLGA algorithms for the simulation of the diffusion equation and Burgers equation on a one-dimensional lattice with two qubits per lattice site on a type-II quantum computer. These QLGA algorithms have been described in “Quantum lattice-gas model for the diffusion equation”, by J. Yepez, published in International Journal of Modern Physics C 12 (2001) 1285-1303, and “Quantum lattice-gas model for the burgers equation”, by J. Yepez, published in Journal of Statistical Physics 107 (2002) 203-224.

Although the aforementioned QLGA models make the simulation of classical physics possible on quantum computers, several drawbacks still need to be addressed before they can provide a more efficient alternative to the classical LGA. Notably, a major drawback of these QLGA models is that they require one qubit per lattice site.

Furthermore, even though there are a variety of other methods for solving the fluid flow equations on quantum devices already available: for example, ranging from solving linearized differential equations using linear system solvers to using the lattice Boltzmann-based models and solving the hydrodynamic Schrödinger equation, what makes the QLGA so appealing for simulating fluid flows (or some other physical processes) on quantum devices is that all of these other methods still suffer from the same major drawback, namely, nonlinearity.

Therefore, in light of the foregoing discussion, there exists a need to overcome the aforementioned drawbacks.

### SUMMARY

The present disclosure seeks to provide a method of setting up a quantum circuit for a lattice gas automata simulation. The present disclosure also seeks to provide a quantum computer or a quantum emulator that is configured to execute the aforementioned method. The present disclosure further seeks to provide a computer program product having computer program instructions stored thereon, the computer program instructions being executable by at least one processor in a classical computer to control a quantum computer or a quantum emulator to perform the aforementioned method. The aim of the present disclosure is achieved by a method, a quantum computer or a quantum emulator, and a computer program product, as defined in the appended independent claims to which reference is made to. Advantageous features are set out in the appended dependent claims.

Throughout the description and claims of this specification, the words “comprise”, “include”, “have”, and “contain” and variations of these words, for example “comprising” and “comprises”, mean “including but not limited to”, and do not exclude other components, items, integers or steps not explicitly disclosed also to be present. Moreover, the singular encompasses the plural unless the context otherwise requires. In particular, where the indefinite article is used, the specification is to be understood as contemplating plurality as well as singularity, unless the context requires otherwise.

### BRIEF DESCRIPTION OF THE DRAWINGS

FIG. 1 depicts a two-dimensional lattice having a size of N×M lattice sites;

FIG. 2 depicts a schematic diagram of a quantum circuit for a lattice gas automata simulation;

FIG. 3A depicts a part of a quantum circuit for a lattice gas automata simulation, in accordance with an embodiment of the present disclosure;

FIG. 3B depicts another part of the quantum circuit, in accordance with an embodiment of the present disclosure;

FIGS. 4A, 4B and 4C depict examples of experiments in which a comparison has been made between the classical LGA model and a new QLGA model for different time steps t=0, t=160, t=320, respectively, pursuant to an embodiment of the present disclosure; and

FIGS. 5A, 5B and 5C show how simulation behaves in a presence of noise for different time steps t=2, t=16, t=24, respectively, pursuant to an embodiment of the present disclosure.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practising the present disclosure are also possible.

The present disclosure provides a new method for simulating fluid flows using a new QLGA model on a quantum device (namely, a quantum computer or a quantum emulator). To begin with, there will be described some elements of the QLGA model as follows:
1. The QLGA model is applied on a two-dimensional lattice, which is a regular lattice in which lattice sites cover a two-dimensional space. The characteristics of the two-dimensional lattice play a major role in the modelling capacity of the QLGA. Specific lattice symmetries are often necessary for the simulation of partial differential equations. In the new QLGA model, periodic lattice boundaries are assumed.
2. A set of Boolean variables, referred to as “channels”, are represented as follows:

n(r,t)={n₁(r,t),n₂(r,t),n₃(r,t),n₄(r,t)}
such that n∈C, wherein “C” represents a set of all channels, “r” represents a given lattice site in the two-dimensional lattice, and “t” indicates a given time step. The channels provide information about the occupation (nᵢ=1) or lack (nᵢ=0) of particles defined at each time step t and each lattice site r.
3. A following micro-dynamical equation can be used to describe the time evolution of particles moving from a lattice site situated at a lattice site “r” to a neighbouring lattice site “r+vᵢ” with a given velocity “vᵢ”:

$${n}_{i} ( r + {v}_{i} , t + 1 ) = {n}_{i} ( r , t ) + {Δ}_{i} [ n ( r , t ) ]$$

The function Δᵢ: C-->C is referred to as a “collision operator”, throughout the present disclosure.
4. In simulations and model interpretation, the physics is not captured by a microscopic evolution of any system but instead by a macroscopic behaviour that emerges from a local interaction and propagation of particles. Taking this fact into account, an average value of the channel occupation number <nᵢ> is introduced. In other words, derivation of physical variables is managed by introducing an averaged value of the channel occupation <nᵢ>, where a mass density is calculated as follows:

$$ρ = {Σ}_{i} 〈 {n}_{i} 〉$$

Moreover, a momentum density is calculated as follows:

$$ρ {u}_{α} = {Σ}_{i} 〈 {n}_{i} 〉 {v}_{i α}$$

where “p” denotes mass density, “u” denotes a macroscopic velocity, and “v” denotes a particle velocity (namely, a velocity of a given particle). An average can be calculated over an ensemble of experiments with different initial conditions or by performing spatial averaging using sub-lattices of the two-dimensional lattice. This allows to calculate an average occupancy of a lattice site on the macroscopic scale, thereby reducing the noise.

It is also noted that the collision operator Δᵢ is applied to every lattice site at the same time, obeying the conditions of conserving mass and momentum as follows:

ΣᵢΔᵢ(n)=0

ΣᵢvᵢΔᵢ(n)=0

This means that the time evolution is synchronous for each lattice site. At the same time, the fluid dynamics are homogeneous, meaning that the collision rules are equal in every lattice site.

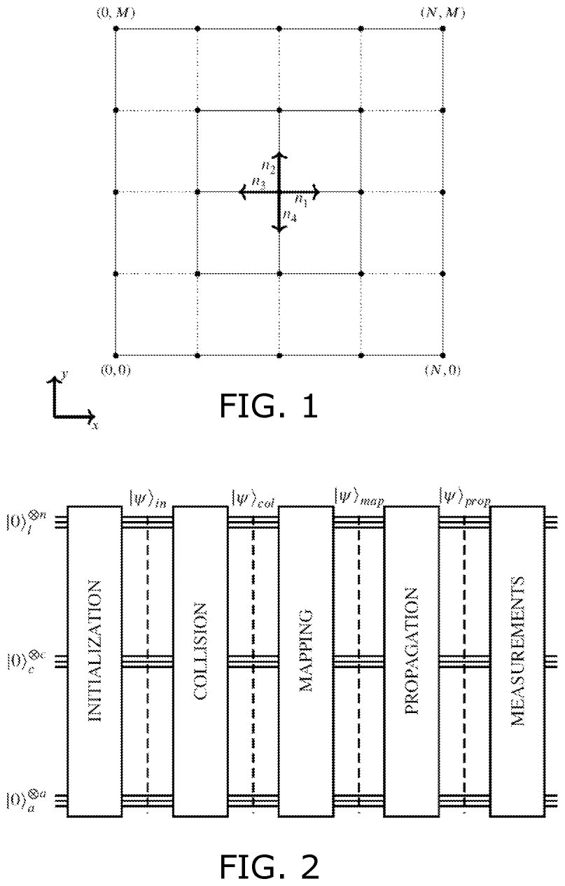

The aforementioned elements of the QLGA model have been illustrated in FIG. 1, which depicts a two-dimensional lattice having a size of N×M lattice sites. It will be appreciated that for the sake of simplicity, the new QLGA model will be described using a square lattice (namely, N=M), but the new QLGA model is not restricted to such.

The new QLGA model is based on a two-dimensional HPP model, which originally developed as a cellular automaton to recreate fluid dynamics in 1970s by Hardy, Pomeau and de Pazzis. Similar to the HPP model, the new QLGA model involves discrete dynamics of particles moving and colliding on the two-dimensional lattice, whilst conserving the momentum and the particle count. The new QLGA model makes use of the von Neumann method, meaning that only vertical and horizontal neighbours are given four different channels, depicted as n₁, n₂, n₃ and n₄ in FIG. 1.

In this regard, there are only two simple collision rules. First, if two particles going down and up collide at a lattice site as described by a channel state |0101>, an output will be one particle moving left and another particle moving right, giving a channel state |1010>. The opposite applies when two particles going left and right collide at a lattice site, giving an output of one particle moving up and another particle moving down. The collision operator can thus be seen as an identity for all the states except:

$$\vert 1010 > -- > \vert 0101 > , and$$

$$\vert 0101 > -- > \vert 1010 > .$$

In other words, all other states remain unaffected by the collision process, ensuring that the mass and momentum are conserved. This property makes the dynamics self-dual and satisfies detailed balance. During a propagation step, each particle is advanced along a prescribed direction.

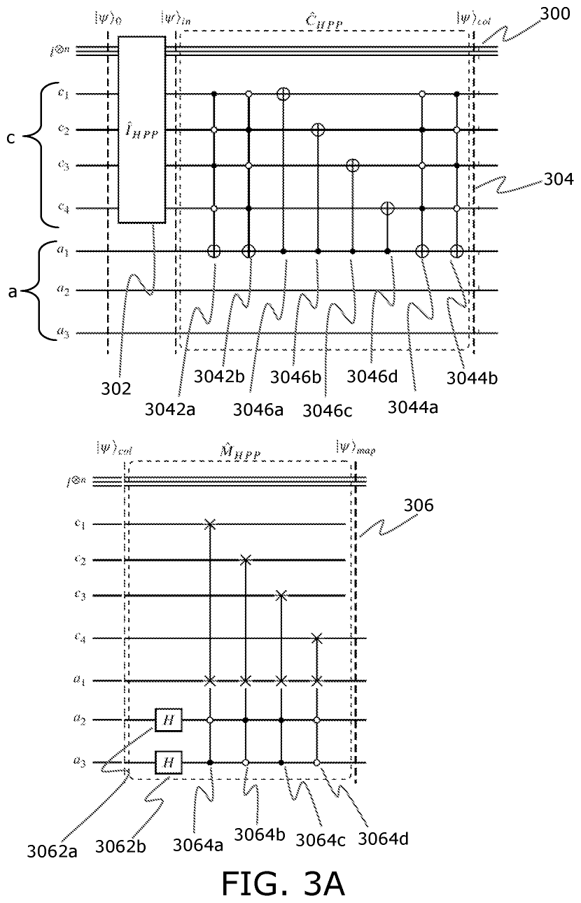

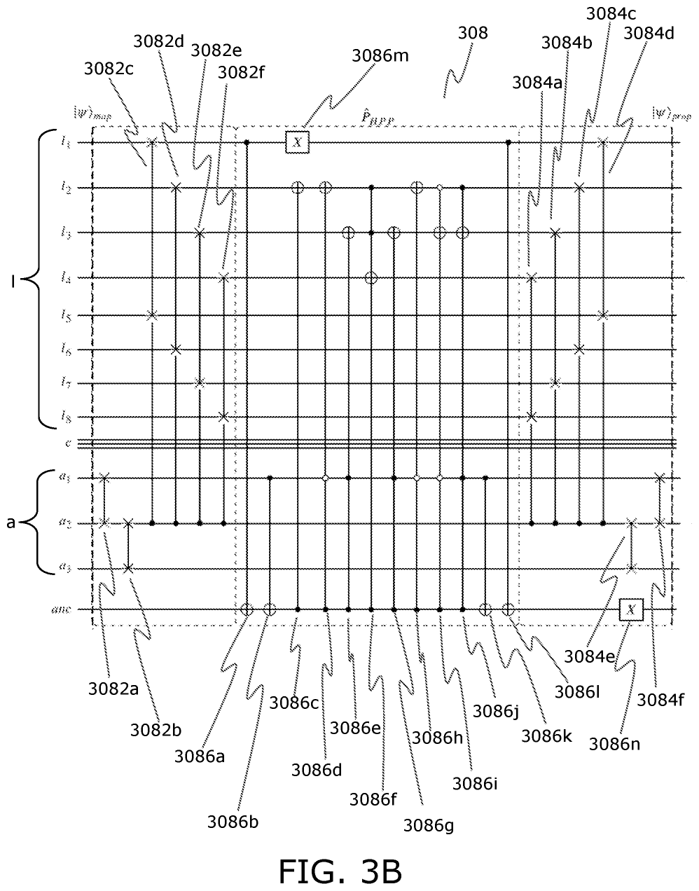

Next, FIG. 2 depicts a schematic diagram of a quantum circuit for a lattice gas automata simulation. The quantum circuit comprises an initialization step, a collision step, a mapping step, a propagation step, and a measurement step, marked INITIALIZATION, COLLISION, MAPPING, PROPAGATION and MEASUREMENTS, respectively, in FIG. 2. In this regard, the quantum circuit mostly follows the structure of the classical LGA. Each of these steps requires a particular algorithm design that is tailored to quantum devices. As will be illustrated later in FIG. 3, the superposition principle for the representation of the two-dimensional lattice in LGA provides a certain level of flexibility for building the initialization and collision steps. Moreover, the mapping step (also called as superposition mapping) between the collision step and the propagation step is introduced, in order to enable use of the state-of-the-art quantum algorithms for the propagation step. Furthermore, the new QLGA model uses a binary representation of the channels, as in the classical LGA.

The initialization step is one of the most important steps of any quantum algorithm with complex initial conditions. Initializing non-structured data can lead to the number of multi-controlled gates growing exponentially with respect to the number of qubits. Several methods have been researched to reduce the complexity of the initialization step, for example, such as described in “Transformation of quantum states using uniformly controlled rotations”, by M. Mottonen et al., published in Quantum Information and Computation 5 (2005) 467-473, “A divide-and-conquer algorithm for quantum state preparation”, by I. F. Araujo et al., published in Scientific Reports 11 (2021); and “Efficient boolean methods for preparing uniform quantum states”, by F. Mozafari et al., published in IEEE Transactions on Quantum Engineering 2 (2021) 1-12.

However, for purely practical reasons, the reverse iterative procedure proposed by Shende et al. has been utilised, with focus on the implementation of the LGA itself, in an example embodiment of the present disclosure. This reverse iterative procedure has been described in “Synthesis of quantum-logic circuits”, by V. Shende et al., published in IEEE Transactions on Computer-Aided Design of Integrated Circuits and Systems 25 (2006) 1000-1010. Optionally, in this regard, the initialization step is performed using a first equation:

$$\begin{matrix}{{{{{\vert ψ 〉}_{in} {\hat{I}}_{HPP} \vert ψ 〉}_{0} = {\hat{I}}_{HPP} ( \vert 0 〉}_{l}^{⊗ n} ⊗ \vert 0 〉}_{c}^{⊗ 4} ) ⊗ \vert 0 〉}_{a}^{⊗ 3} \\ {{{{{= \frac{1}{\sqrt{{2}^{n}}} {\sum }_{i = 0}^{{2}^{n} - 1} {d}_{i} ⊗ \vert 0 〉}_{a}^{⊗ 3} = \frac{1}{\sqrt{{2}^{n}}} {\sum }_{i = 0}^{{2}^{n} - 1} \vert {\overbrace{{l}_{1} ... . {l}_{n}}}^{r} \vert {c}_{1} {c}_{2} {c}_{3} {c}_{4} 〉}_{i} ⊗ \vert 0 〉}_{a 1} ⊗ \vert 0 〉}_{a 2} ⊗ \vert 0 〉}_{a 3}\end{matrix}$$

wherein “I_{HPP}” represents the encoding of the initial channel occupancy as an operator, so that the initial quantum state |ψ>ᵢₙ will be as represented by the first equation above.

In the initialization step, a two-dimensional lattice is encoded in the superposition of basis states of a position register “I” with n (=log₂ N) qubits, where N is the number of lattice sites in the lattice. Additionally, a first ancilla register “a” having three ancilla qubits is used for the switch from the binary representation of the channels to the superposition. The first ancilla register is not needed for the encoding itself, but it is used later for the collision step, the mapping step and the propagation step. In this regard, the propagation step may be implemented using well-known state shift techniques, for example, such as described in “Efficient parallelization of quantum basis state shift”, by Ljubomir Budinski et al., published in Quantum Science and Technology 8 (2023) 045031, and “Efficient and scalable quantum walk algorithms via the quantum fourier transform”, by A. Shakeel, published in Quantum Information Processing 19 (2020). In such a case, an additional variable ancilla register having a single qubit may be introduced during the propagation step, if needed.

In the first equation, “dᵢ” represents binary strings that are composed from the qubits (I₁, I₂, . . . Iₙ) of the position register “I” encoding positions of lattice sites and the four qubits (c₁, c₂, c₃, c₄) of the channel register “c” encoding occupancies of four channels per lattice site. For example, a binary string |00010101> would refer to the occupancy of |0101> at the lattice site positioned at |0001>. It will be appreciated that the contents of the active channel |c₁c₂c₃c₄>ᵢ varies depending on the position “i”, and each qubit encodes a particular channel. A particle with a direction “nᵢ” is encoded with a corresponding qubit “cᵢ”. It will be appreciated that these binary strings represent basis states of a sub-system only without ancilla qubits, and do not represent basis states of the entire system. With the first ancilla register “a”, these binary strings repeat as substrings of complete binary strings corresponding to the basis states of the entire system, according to the tensor products with the ancilla qubits.

In all the equations, that follow, there will be considered a sum over all the lattice sites i∈{0, . . . , 2ⁿ⁻¹}. In the initiation step, the x_{i,j} and y_{i,j} coordinates of the lattice sites are mapped into one-dimensional space using the following relation:

$${r}_{k} = {y}_{i , j} + {x}_{i , j} ( N - 1 ) , with i , j = 0 , … , N - 1 and k = 0 , … , ( {N}^{2} - 1 )$$

It will be appreciated here that a square lattice configuration has been assumed with N=M, for the sake of simplicity only.

Next, in the collision step, a switch is performed between two particular occupancy sub-states as mentioned in the collision rules earlier. Since the occupancy of the channels is stored only in the channel register “c”, the collision step involves only those four qubits of the channel register. Optionally, in this regard, the collision step is applied using a second equation:

$${{{{{{\vert ψ 〉}_{col} = {\hat{C}}_{HPP} \vert ψ 〉}_{in} = \frac{1}{\sqrt{{2}^{n}}} {\sum }_{i} \vert {l}_{1} ... . {l}_{n} \vert {c}_{1}^{′} {c}_{2}^{′} {c}_{3}^{′} {c}_{4}^{′} 〉}_{i} ⊗ \vert 0 〉}_{a}^{⊗ 3} = \frac{1}{\sqrt{{2}^{n}}} {\sum }_{i} \vert {l}_{1} ... . {l}_{n} \vert σ ( {c}_{1} {c}_{2} {c}_{3} {c}_{4} ) 〉}_{i} ⊗ \vert 0 〉}_{a}^{⊗ 3}$$

wherein σ represents a channel map that maps channel states, and “C_{HPP}” represents the gate sequence as an operator, thereby obtaining the new state |ψ>_{col}. Moreover, the collided channel is denoted by |c′₁c′₂c′₃c′₄>. Optionally, in this regard, the channel map maps the channel states according to following collision rules:
a collision between one particle moving down and another particle moving up at a lattice site and represented by a channel state |0101> is mapped to an output in which one particle moves left and another particle moves right as represented by a channel state |1010>;
a collision between one particle moving left and another particle moving right at a lattice site and represented by the channel state |1010> is mapped to an output in which one particle moves up and another particle moves down as represented by the channel state |0101>; and
any other channel state remains unchanged.

This channel map can be represented as follows:

$$σ ( {c}_{1} {c}_{2} {c}_{3} {c}_{4} ) = \{ \begin{matrix}1010 , & for {c}_{1} {c}_{2} {c}_{3} {c}_{4} = 0101 \\ 0101 , & for {c}_{1} {c}_{2} {c}_{3} {c}_{4} = 1010 \\ {c}_{1} {c}_{2} {c}_{3} {c}_{4} , & otherwise\end{matrix} .$$

Subsequently, the occupancy of each channel is propagated spatially according to a prescribed velocity of a particular LGA model. For the new QLGA model, the particles residing on the channel pointing to the right/left direction are propagated one step at a time in the right/left direction; likewise, the particles residing on the channel pointing to the up/down direction are propagated one step at a time in the up/down direction. The practical implementation of this movement is straightforward classically, but the quantum implementation is more involved. According to an example embodiment, a state shift method as detailed in “Efficient parallelization of quantum basis state shift”, by Ljubomir Budinski et al., published in Quantum Science and Technology 8 (2023) 045031 is used. This requires a rearrangement of the qubit encoding. Particularly, in order to propagate each qubit state independently in the channel register “c”, the occupancy sub-state needs to be decomposed. In this regard, each qubit from the channel register “c” is mapped into a superposition of states using the first ancilla register “a” entangled with the lattice sites. This is achieved by first bringing the ancilla qubits “a₂” and “a₃” from the first ancilla register “a” into a superposition state using Hadamard gates followed by four multi-control SWAP gates between the channel register “c” and the first ancilla register “a”, as depicted in FIG. 3A later.

Optionally, in this regard, the mapping step is applied using a third equation:

$$\begin{matrix}{{\vert ψ 〉}_{map} = {\hat{M}}_{HPP} \vert ψ 〉}_{col} \\ {{{= {MCSWAP}_{a - c} \frac{1}{\sqrt{{2}^{n}}} {\sum }_{i} \vert {l}_{1} ... . {l}_{n} \vert {c}_{1}^{′} {c}_{2}^{′} {c}_{3}^{′} {c}_{4}^{′} 〉}_{i} ⊗ \vert 0 〉}_{a 1} ⊗ \\ H \vert 0 〉}_{a2} ⊗ H {\vert}_{a3} \\ {{= \frac{1}{2 \sqrt{{2}^{n}}} ( {\sum }_{i} \vert {l}_{1} ... . {l}_{n} \vert {c}_{1}^{′} {c}_{2}^{′} {c}_{3}^{′} {a}_{1} 〉}_{i} ⊗ \vert {c}_{4}^{′} 〉 ⊗ \vert 00 〉}_{a 2 , a 3} + \\ {{{\sum }_{i} \vert {l}_{1} ... . {l}_{n} \vert {c}_{1}^{′} {a}_{1} {c}_{3}^{′} {c}_{4}^{′} 〉}_{i} ⊗ \vert {c}_{2}^{′} 〉 ⊗ \vert 10 〉}_{a 2 , a 3} + \\ {{{\sum }_{i} \vert {l}_{1} ... . {l}_{n} \vert {a}_{1} {c}_{2}^{′} {c}_{3}^{′} {c}_{4}^{′} 〉}_{i} ⊗ \vert {c}_{1}^{′} 〉 ⊗ \vert 01 〉}_{a 2 , a 3} + \\ {{{\sum }_{i} \vert {l}_{1} ... . {l}_{n} \vert {c}_{1}^{′} {c}_{2}^{′} {a}_{1} {c}_{4}^{′} 〉}_{i} ⊗ \vert {c}_{3}^{′} 〉 ⊗ \vert 11 〉}_{a 2 , a 3} )\end{matrix} .$$

Using the third equation, each channel of the channel register “c” is mapped into the sub-states marked with the corresponding state of the ancilla qubits “a₂” and “a₃”. As a result, an equal superposition of the lattice sites (represented by the position register “I”) and each channel (represented by the channel register “c”) is obtained. This allows to apply one-step shift in different directions independently for each channel.

Finally, the propagation of the particles along the corresponding directions can be implemented with the increment and decrement operations on the basis states. In the new QLGA model, along a horizontal direction, the increment moves the particle n1 one step to the right, while the decrement moves the particle n3 one step to the left (see FIG. 1). Along a vertical direction, the increment moves the particle n2 one step to the up direction, while the decrement moves the particle n4 one step to the down direction (see FIG. 1).

It will be appreciated that several quantum algorithms (namely, quantum circuits) exist for these shift operators, as they are crucial in several applications, such as the quantum random walk, matrix block encoding, and the quantum lattice e Boltzmann method. For an efficient implementation, a shift based on the quantum Fourier transformation has been proposed by Shakeel in “Efficient and scalable quantum walk algorithms via the quantum fourier transform”, published in Quantum Information Processing 19 (2020), and a parallel shift method by Budinski et al. in “Efficient parallelization of quantum basis state shift”, published in Quantum Science and Technology 8 (2023) 045031.

An implementation of the parallel shift for the new QLGA model in the case of 256 lattice sites (namely, eight qubits in the position register “I”) is illustrated in conjunction with FIG. 3B, with an additional variable ancilla register having a single qubit. In this regard, propagation in four different orthogonal directions on the two-dimensional lattice can be constructed by sandwiching a quantum circuit for the left/right propagation between two symmetrical sets of controlled SWAP gates. This gives a permutation of the sub-states for the particles propagating in the left and right directions, effectively parallelizing the four directions.

It will be appreciated that expansion of the aforementioned parallel shift to the larger number of lattice sites is straightforward. It will be appreciated that any other shift algorithm can alternatively be utilised, instead of the aforementioned parallel shift. Applying the propagation operator “P_{HPP}” on state |ψ>ₘₐₚ results in a new state, |ψ>ₚᵣₒₚ.

Optionally, in this regard, the propagation step is applied using a fourth equation:

$$\begin{matrix}{{{{\vert ψ 〉}_{prop} = {\hat{P}}_{HPP} \vert ψ 〉}_{map} = {\hat{P}}_{HPP} \frac{1}{2 \sqrt{2}} ( {\sum }_{i} \vert {l}_{1} ... . {l}_{n} \vert {c}_{1}^{′} {c}_{2}^{′} {c}_{3}^{′} {a}_{1} 〉}_{i} ⊗ \vert {c}_{4}^{′} 〉 ⊗ \\ \vert 00 〉}_{a 2 , a 3} + \\ {{{\sum }_{i} \vert {l}_{1} ... . {l}_{n} \vert {c}_{1}^{′} {a}_{1} {c}_{3}^{′} {c}_{4}^{′} 〉}_{i} ⊗ \vert {c}_{2}^{′} 〉 ⊗ \vert 10 〉}_{a 2 , a 3} + \\ {{{\sum }_{i} \vert {l}_{1} ... . {l}_{n} \vert {a}_{1} {c}_{2}^{′} {c}_{3}^{′} {c}_{4}^{′} 〉}_{i} ⊗ \vert {c}_{1}^{′} 〉 ⊗ \vert 01 〉}_{a 2 , a 3} + \\ {{{\sum }_{i} \vert {l}_{1} ... . {l}_{n} \vert {c}_{1}^{′} {c}_{2}^{′} {a}_{1} {c}_{4}^{′} 〉}_{i} ⊗ \vert {c}_{3}^{′} 〉 ⊗ \vert 11 〉}_{a 2 , a 3} ) \\ {{{= \frac{1}{2 \sqrt{2}} ( {\sum }_{i} \vert {l}_{1} ... . {l}_{n} 〉}_{i} ⊗ \vert {c}_{1}^{′} {c}_{2}^{′} {c}_{3}^{′} {a}_{1} 〉}_{{π}_{+} ( i )} ⊗ \vert {c}_{4}^{′} 〉 ⊗ \\ \vert 00 〉}_{a 2 , a 3} + \\ {{{{\sum }_{i} \vert {l}_{1} ... . {l}_{n} 〉}_{i} ⊗ \vert {c}_{1}^{′} {a}_{1} {c}_{3}^{′} {c}_{4}^{′} 〉}_{{π}_{-} ( i )} ⊗ \vert {c}_{2}^{′} 〉 ⊗ \vert 10 〉}_{a 2 , a 3} + \\ {{{{\sum }_{i} \vert {l}_{1} ... . {l}_{n} 〉}_{i} ⊗ \vert {a}_{1} {c}_{2}^{′} {c}_{3}^{′} {c}_{4}^{′} 〉}_{{π}_{+ p} ( i )} ⊗ \vert {c}_{1}^{′} 〉 ⊗ \vert 01 〉}_{a 2 , a 3} + \\ {{{{\sum }_{i} \vert {l}_{1} ... . {l}_{n} 〉}_{i} ⊗ \vert {c}_{1}^{′} {c}_{2}^{′} {a}_{1} {c}_{4}^{′} 〉}_{{π}_{- p} ( i )} ⊗ \vert {c}_{3}^{′} 〉 ⊗ \vert 11 〉}_{a 2 , a 3} )\end{matrix}$$

wherein p is equal to a number of lattice sites along a given dimension. It will be appreciated that in a case where the two-dimensional lattice is assumed as a square lattice, the number of lattice sites along both directions are equal.

In the above equation, π+ (i) and π−(i) account for periodic single-step shifts in a first dimension as follows:

$${π}_{+} ( i ) = \{ \begin{matrix}i + 1 , & for i ∈ \{ kp , … , ( k + 1 ) p - 2 \} and k ∈ \{ 0 , … , p - 1 \} \\ kp , & for i = ( k + 1 ) p - 1 and k ∈ \{ 0 , … , p - 1 \}\end{matrix}$$

$$and$$

$${π}_{-} ( i ) = \{ \begin{matrix}i - 1 , & for i ∈ \{ kp + 1 , … , ( k + 1 ) p - 1 \} and k ∈ \{ 0 , … , p - 1 \} \\ ( k + 1 ) p - 1 , & for i = kp and k ∈ \{ 0 , … , p - 1 \}\end{matrix}$$

and π+p(i) and π−p (i) account for periodic shifts in a second dimension as follows:

$${π}_{+ p} ( i ) = \{ \begin{matrix}i + p , & for i ∈ \{ kp , … , ( k + 1 ) p - 1 \} and k ∈ \{ 0 , … , p - 2 \} \\ i - {p}^{2} + p , & for i ∈ \{ kp , … , ( k + 1 ) p - 1 \} and k = p - 1\end{matrix}$$

$$and$$

$${π}_{- p} ( i ) = \{ \begin{matrix}i - p , & for i ∈ \{ kp , … , ( k + 1 ) p - 1 \} and k ∈ \{ 1 , … , p - 2 \} \\ i + {p}^{2} - p , & for i ∈ \{ kp , … , ( k + 1 ) p - 1 \} and k = 0\end{matrix} .$$

It will be appreciated here that periodic lattice boundaries are assumed. Namely, the lattice indexing is assumed to be periodic. The binary strings “dᵢ” representing the position and the channels have to split, as the channel information is moved along the directions on the lattice. With this propagation step, one time step of the new QLGA model is completed.

The position registers “I” and the ancilla register “a” are measured at the end of each time step. As the encoding in this new QLGA model is binary, the states do not carry any information in the amplitudes or the phases. Information about the occupancy of the channel is stored in the ancilla qubit “a₁”, and the particular channel is identified with the states of the ancilla qubits “a₂” and “a₃”. In other words, when the state |00>a₂a₃ is observed, the ancilla qubit “a₁” denotes the right moving channel, while an observation of the state |10> a₂a₃ means that the ancilla qubit “a₁” denotes the up moving channel, and so on. These measurement results are then used to prepare the initial state for the next time step.

Referring next to FIG. 3A, depicted is a detailed diagram of a part of a quantum circuit 300 for a lattice gas automata simulation, in accordance with an embodiment of the present disclosure. In this regard, an embodiment of the present disclosure provides a method of setting up the quantum circuit 300 for a lattice gas automata simulation, the method comprising:
performing an initialization step 302 by setting up, for the quantum circuit 300, a position register I, a channel register c and a first ancilla register a, wherein the position register I comprises a plurality of qubits (I₁, I₂, . . . Iₙ), the channel register c comprises four qubits c₁, c₂, c₃, and c₄, and the first ancilla register a comprises three ancilla qubits a₁, a₂ and a₃; and
applying to the position register I, the channel register c and the first ancilla register a in a sequential order:
   (i) a collision step 304 constructed using a first set of multi-controlled gates 3042a-3042b, a second set of multi-controlled gates 3044a-3044b, and four CX gates 3046a-3046d arranged between the first set and the second set, the collision step 304 being applied to the channel register c and the first ancilla register a;
   (ii) a mapping step 306 constructed using two Hadamard gates 3062a-3062b and four multi-controlled SWAP gates 3064a-3064d, the mapping step 306 being applied to the channel register c and the first ancilla register a; and
   (iii) a propagation step 308 being applied to the position register I and the first ancilla register a.

Optionally, in the method, a two-dimensional lattice is represented by a grid of lattice sites (for example, an N×M grid as shown in FIG. 1), wherein in the initialization step 302, the qubits of the position register I are used to encode positions of the lattice sites in said grid. In this regard, the position register I encodes lattice sites using bitstrings that are defined by qubit tensor products. As an example, assuming a square lattice, with 8 qubits in the position register I, there would be 256 (=2\hat{ }8) lattice sites. It will be appreciated that the size (namely, the number of qubits) of the position register I can be arbitrary; a conceivable minimum being 2 qubits for a 2×2 lattice, and in theory, having no upper limit. It will also be appreciated here that for the sake of simplicity, the two-dimensional lattice can be assumed as a square lattice, but the method and the quantum circuit 300 are not restricted to such. Moreover, it is assumed that the two-dimensional lattice is finite, and is completely indexed by the position register I. Periodicity is assumed at the boundaries of the lattice, so that it loops around itself.

Moreover, the position register I is used to index the lattice sites, over which the occupancies encoded in the channel states are initialized. Optionally, in this regard, in the initialization step 302, the four qubits c₁, c₂, c₃ and c₄ of the channel register c are initialized to encode respective occupancies of four channels per lattice site. The four channels correspond to particle movement along respective ones of four directions in the two-dimensional lattice (which directions are shown as n₁, n₂, n₃ and n₄ in FIG. 1).

It will be appreciated that the new quantum circuit 300 demonstrates LGA as a quantum-native method for simulating fluid flow. In particular, the new QLGA model demonstrated by the new quantum circuit 300 uses the quantum superposition property to encode the structure of the two-dimensional lattice. Moreover, the drawback of lattice representation in existing QLGA models (namely, requiring one qubit per lattice site) has been addressed by exploiting the superposition property of all lattice sites. As a result, the quantum circuit 300 scales logarithmically with the number of states and is capable of simulating LGA with logarithmic complexity in the number of CX gates, thereby exhibiting an exponential speedup for one time step and demonstrating a potential for significant computational advantage in systems with a large number of states. This is in contrast to the classical LGA and other existing QLGA models, which have linear complexity with respect to the number of lattice sites. The quantum circuit 300 is based on a two-dimensional HPP model, and is interchangeably referred to as the “new QLGA model”, throughout the present disclosure.

Additionally, the quantum circuit 300 (namely, the new QLGA model) is more resilient to quantum noise than the closely-related quantum lattice Boltzmann method, which is very sensitive to changes in the state amplitudes. Moreover, the quantum circuit 300 (namely, the new QLGA model) also solves the issue of simulating nonlinearities, as they are introduced as a result of local interactions between particles, exhibiting a complex behaviour.

In accordance with an embodiment of the present disclosure, in the collision step 304, the first set of multi-controlled gates 3042a-3042b comprise in a sequential order:
a first multi-controlled gate 3042a that uses a first qubit c₁ and a third qubit c₃ of the channel register c as controls corresponding to a state of |1>, a second qubit c₂ and a fourth qubit c₄ of the channel register c as controls corresponding to a state of |0>, and a first ancilla qubit a₁ of the first ancilla register a as a target; and
a second multi-controlled gate 3042b that uses the first qubit c₁ and the third qubit c₃ of the channel register c as controls corresponding to the state of |0>, the second qubit c₂ and the fourth qubit c₄ of the channel register c as controls corresponding to the state of |1>, and the first ancilla qubit a₁ of the first ancilla register a as a target.

In the collision step 304, the four CX gates 3046a-3046d are arranged after the first set of multi-controlled gates 3042a-3042b and before the second set of multi-controlled gates 3044a-3044b, wherein the four CX gates 3046a, 3046b, 3046c and 3046d use in a sequential order, respectively: the first qubit c₁, the second qubit c₂, the third qubit c₃ and the fourth qubit c₄ of the channel register c as respective targets. Each of the four CX gates 3046a-3046d use the first ancilla qubit a₁ of the first ancilla register a as a control corresponding to the state of |1>.

Moreover, in the collision step 304, the second set of multi-controlled gates 3044a-3044b comprises in a sequential order:
a third multi-controlled gate 3044a that uses the first qubit c₁ and the third qubit c₃ of the channel register c as controls corresponding to the state of |0>, the second qubit c₂ and the fourth qubit c₄ of the channel register c as controls corresponding to the state of |1>, and the first ancilla qubit a₁ of the first ancilla register a as a target; and
a fourth multi-controlled gate 3044b that uses the first qubit c₁ and the third qubit c₃ of the channel register c as controls corresponding to the state of |1>, the second qubit c₂ and the fourth qubit c₄ of the channel register c as controls corresponding to the state of |0>, and the first ancilla qubit a₁ of the first ancilla register a as a target.

In accordance with an embodiment of the present disclosure, in the mapping step 306, one of the two Hadamard gates (namely a Hadamard gate 3062a) is applied to a second ancilla qubit a₂ of the first ancilla register a, while another of the two Hadamard gates (namely a Hadamard gate 3062b) is applied to a third ancilla qubit a₃ of the first ancilla register a, the two Hadamard gates 3062a-3062b being applied before the four multi-controlled SWAP gates 3064a-3064d.

Moreover, in the mapping step 306, the four multi-controlled SWAP gates 3064a-3064d comprise in a sequential order:
a first multi-controlled SWAP gate 3064a that is applied between the first qubit c₁ of the channel register c and the first ancilla qubit a₁ of the first ancilla register a, and that uses the second ancilla qubit a₂ of the first ancilla register a as a control corresponding to the state of |0> and the third ancilla qubit as of the first ancilla register a as a control corresponding to the state of |1>;
a second multi-controlled SWAP gate 3064b that is applied between the second qubit c₂ of the channel register c and the first ancilla qubit a₁ of the first ancilla register a, and that uses the second ancilla qubit a₂ of the first ancilla register a as a control corresponding to the state of |1> and the third ancilla qubit a₃ of the first ancilla register a as a control corresponding to the state of |0>;
a third multi-controlled SWAP gate 3064c that is applied between the third qubit c₃ of the channel register c and the first ancilla qubit a₁ of the first ancilla register a, and that uses the second ancilla qubit a₂ and the third ancilla qubit a₃ of the first ancilla register a as controls corresponding to the state of |1>; and
a fourth multi-controlled SWAP gate 3064d that is applied between the fourth qubit c₄ of the channel register c and the first ancilla qubit a₁ of the first ancilla register a, and that uses the second ancilla qubit a₂ and the third ancilla qubit a₃ of the first ancilla register a as controls corresponding to the state of |0>.

With reference to FIG. 3A, there is shown only a part of the quantum circuit 300, which part comprises the initialization step 302, the collision step 304 and the mapping step 306. It will be appreciated that the propagation step 308 can be performed using various different quantum sub-circuits. One example quantum sub-circuit that can be utilised to perform the propagation step 308 will now be illustrated in conjunction with FIG. 3B.

With reference to FIG. 3B, the two-dimensional lattice is assumed to be a square lattice having a size of 256 lattice sites. Thus, all the lattice sites of this lattice can be encoded using 8 qubits only. Accordingly, in such a case, the position register I comprises 8 qubits I₁, I₂, I₃, I₄, I₅, I₆, I₇ and I₈.

Moreover, in the example quantum sub-circuit of the propagation step 308, a variable ancilla register having a single ancilla qubit anc is also introduced. In accordance with an embodiment of the present disclosure, the propagation step 308 comprises:
a first set of SWAP gates 3082a-3082f;
a second set of SWAP gates 3084a-3084f; and
a cascade of gates 3086a-3086n, arranged between the first set of SWAP gates 3082a-3082f and the second set of SWAP gates 3084a-3084f.

The first set of SWAP gates 3082a-3082f comprises in a sequential order:
a first SWAP gate 3082a that is applied between the first ancilla qubit a₁ and the second ancilla qubit a₂ of the first ancilla register a;
a second SWAP gate 3082b that is applied between the second ancilla qubit a₂ and the third ancilla qubit a₃ of the first ancilla register a;
a first controlled SWAP gate 3082c that is applied between a first qubit I₁ and a fifth qubit I₅ of the position register I, and that uses the second ancilla qubit a₂ of the first ancilla register a as a control corresponding to the state of |1>;
a second controlled SWAP gate 3082d that is applied between a second qubit I₂ and a sixth qubit I₆ of the position register I, and that uses the second ancilla qubit a₂ of the first ancilla register a as a control corresponding to the state of |1>;
a third controlled SWAP gate 3082e that is applied between a third qubit I₃ and a seventh qubit I₇ of the position register I, and that uses the second ancilla qubit a₂ of the first ancilla register a as a control corresponding to the state of |1>; and
a fourth controlled SWAP gate 3082f that is applied between a fourth qubit I₄ and an eighth qubit I₈ of the position register I, and that uses the second ancilla qubit a₂ of the first ancilla register a as a control corresponding to the state of |1>.

The second set of SWAP gates 3084a-3084f comprises in a sequential order:
a fifth controlled SWAP gate 3084a that is applied between the fourth qubit I₄ and the eighth qubit I₈ of the position register I, and that uses the second ancilla qubit a₂ of the first ancilla register a as a control corresponding to the state of |1>;
a sixth controlled SWAP gate 3084b that is applied between the third qubit I₃ and the seventh qubit I₇ of the position register I, and that uses the second ancilla qubit a₂ of the first ancilla register a as a control corresponding to the state of |1>;
a seventh controlled SWAP gate 3084c that is applied between the second qubit I₂ and the sixth qubit I₆ of the position register I, and that uses the second ancilla qubit a₂ of the first ancilla register a as a control corresponding to the state of |1>;
an eighth controlled SWAP gate 3084d that is applied between the first qubit I₁ and the fifth qubit I₅ of the position register I, and that uses the second ancilla qubit a₂ of the first ancilla register a as a control corresponding to the state of |1>;
a third SWAP gate 3084e that is applied between the second ancilla qubit a₂ and the third ancilla qubit a₃ of the first ancilla register a; and
a fourth SWAP gate 3084f that is applied between the first ancilla qubit a₁ and the second ancilla qubit a₂ of the first ancilla register a.

It will be appreciated that the number of controlled SWAP gates in the first set 3082a-3082f and the second set 3084a-3084f depend on the size of the two-dimensional lattice and its lattice representation. For the example case of 256 lattice sites (that are encoded using only eight qubits in the position register I), there are only four controlled SWAP gates in each of the first set 3082a-3082f and the second set 3084a-3084f. If N is equal to a total number of qubits in the position register I, the first controlled SWAP gate of the first set can be considered to be applied between the first qubit I₁ and an (N/2+1)^{th} qubit I_{N/2+1} of the position register I; a last controlled SWAP gate of the first set can be considered to be applied between an N/2^{th} qubit I_{N/2} and an N^{th} qubit I_{N} of the position register I. Moreover, it will be appreciated that the second set of SWAP gates 3084a-3084f is merely a reverse of the first set of SWAP gates 3082a-3082f, and can be devised accordingly.

The cascade of gates 3086a-3086n (arranged between the first set 3082a-3082f and the second set 3084a-3084f) comprises in a sequential order:
a first CX gate 3086a that uses the single ancilla qubit anc of the variable ancilla register as a target and uses the first qubit I₁ of the position register I as a control corresponding to the state of |1>;
a second CX gate 3086b that uses the single ancilla qubit anc of the variable ancilla register as a target and uses the first ancilla qubit a₁ of the first ancilla register a as a control corresponding to the state of |1>;
a third CX gate 3086c that uses the second qubit I₂ of the position register I as a target and uses the single ancilla qubit anc of the variable ancilla register as a control corresponding to the state of |1>;
a first two-controlled gate 3086d that uses the first ancilla qubit a₁ of the first ancilla register a as a control corresponding to the state of |0>, the single ancilla qubit anc of the variable ancilla register as a control corresponding to the state of |1>, and the second qubit I₂ of the position register I as a target;
a second two-controlled gate 3086e that uses the first ancilla qubit a₁ of the first ancilla register a and the single ancilla qubit anc of the variable ancilla register as controls corresponding to the state of |1>, and the third qubit I₃ of the position register I as a target;
a first multi-controlled gate 3086f that uses the second qubit I₂ and the third qubit I₃ of the position register I and the single ancilla qubit anc of the variable ancilla register as controls corresponding to the state of |1>, and the fourth qubit I₄ of the position register I as a target;
a third two-controlled gate 3086g that uses the first ancilla qubit a₁ of the first ancilla register a and the single ancilla qubit anc of the variable ancilla register as controls corresponding to the state of |1>, and the third qubit I₃ of the position register I as a target;
a fourth two-controlled gate 3086h that uses the first ancilla qubit a₁ of the first ancilla register a as a control corresponding to the state of |0>, the single ancilla qubit anc of the variable ancilla register as a control corresponding to the state of |1>, and the second qubit I₂ of the position register I as a target;
a second multi-controlled gate 3086i that uses the second qubit I₂ of the position register I and the first ancilla qubit a₁ of the first ancilla register a as controls corresponding to the state of |0> and the single ancilla qubit anc of the variable ancilla register as a control corresponding to the state of |1>, and the third qubit I₃ of the position register I as a target;
a third multi-controlled gate 3086j that uses the second qubit I₂ of the position register I, the first ancilla qubit a₁ of the first ancilla register a and the single ancilla qubit anc of the variable ancilla register as controls corresponding to the state of |1>, and the third qubit I₃ of the position register I as a target;
a fourth CX gate 3086k that uses the single ancilla qubit anc of the variable ancilla register as a target and uses the first ancilla qubit a₁ of the first ancilla register a as a control corresponding to the state of |1>; and
a fifth CX gate 3086l that uses the single ancilla qubit anc of the variable ancilla register as a target and uses the first qubit I₁ of the position register I as a control corresponding to the state of |1>.

The cascade of gates 3086a-3086n further comprises two X gates, wherein a first X gate 3086m is applied between the first CX gate 3086a and the fifth CX gate 3086l, and a second X gate 3086n is applied after the fifth CX gate 3086l.

It will be appreciated that the number and design of the two-controlled gates and the design of the multi-controlled gates in the cascade of gates 3086a-3086n also depend on the size of the two-dimensional lattice and its lattice representation. Symmetries are well observable and evident in the arrangement of various gates in the cascade of gates 3086a-3086n. As an example, the first CX gate 3086a and the second CX gate 3086b are arranged symmetrically opposite to the fifth CX gate 3086l and the fourth CX gate 3086k, respectively. As another example, the first two-controlled gate 3086d and a second two-controlled gate 3086e are arranged symmetrically opposite to the fourth two-controlled gate 3086h and the third two-controlled gate 3086g, respectively.

It is evident that the first set of SWAP gates 3082a-3082f, the second set of SWAP gates 3084a-3084f and the cascade of gates 3086a-3086n allow for the propagation step 308 to scale logarithmically.

In an embodiment of the present disclosure, the quantum circuit 300, after set up, is used for performing the lattice gas automata simulation. After the propagation step 308 is performed, measurements can be taken for one time step, and the quantum circuit 300 can be repeated from the initialization step 302 for a next time step.

In another aspect, an embodiment of the present disclosure provides a quantum computer or a quantum emulator configured to execute the aforementioned method. The present disclosure also relates to the quantum computer or the quantum emulator that is configured to execute the aforementioned method as described above. Various embodiments and variants disclosed above, with respect to the aforementioned method and the quantum circuit 300, apply mutatis mutandis to the quantum computer or the quantum emulator. In an embodiment, the quantum computer or the quantum emulator is used to perform the lattice gas automata simulation, as described above.

It will be appreciated here that the term “quantum emulator” refers to an emulator for a quantum computer. A quantum emulator can be a classical computer that is configured to emulate the behaviour of a quantum computer.

In a third aspect, an embodiment of the present disclosure provides a computer program product having computer program instructions stored thereon, the computer program instructions being executable by at least one processor in a classical computer to control a quantum computer or a quantum emulator to perform the aforementioned method. The present disclosure also relates to such a computer program product. Various embodiments and variants disclosed above, with respect to the aforementioned method, apply mutatis mutandis to the computer program product. The computer program product can be in a form of a non-transitory computer-readable medium, a software application, or a cloud-based service. The software application may, for example, be downloadable from an App store, or a website that servers as a distribution platform for the software application. The cloud-based service may be implemented as a web-based platform that provides software functionality according to the aforementioned method over a communication network (for example, such as the Internet).

### Experimental Part

There will now be considered an analysis of the gate complexity of the quantum circuit 300 of the new QLGA model as compared to the prior art. The focus of this analysis will be on three main steps that make the core of the QLGA model, namely: the collision step 304, the mapping step 306, and the propagation step 308.

The collision step 304 and the mapping step 306 between binary encoding to superposition scales as O(1), as the number of channels is constant. However, the propagation step 308 depends critically on multi-controlled gates and will be the source for most of the complexity in the quantum algorithm. In the illustrated example embodiment, the propagation step 308 is implemented using the basis state shift, for example, as described in “Efficient parallelization of quantum basis state shift”, by Ljubomir Budinski et al., published in Quantum Science and Technology 8 (2023) 045031. This document provides an extensive complexity analysis for the canonical shift, the Quantum Fourier Transform (QFT) variation, and the parallel shift, together with an outline of an ancilla decomposition of the multi-controlled gates. The results focus on a transpilation with the IBM basis set of gates CX, I, RZ, SX and X using standard compilation techniques. It can be concluded that the best choice for conducting the shift step is the parallel shift algorithm, as it provides a linear scaling n_{CX}(n)=15 (n−6)+149 in terms of CX gates, when the number of working qubits “n” is at least six.

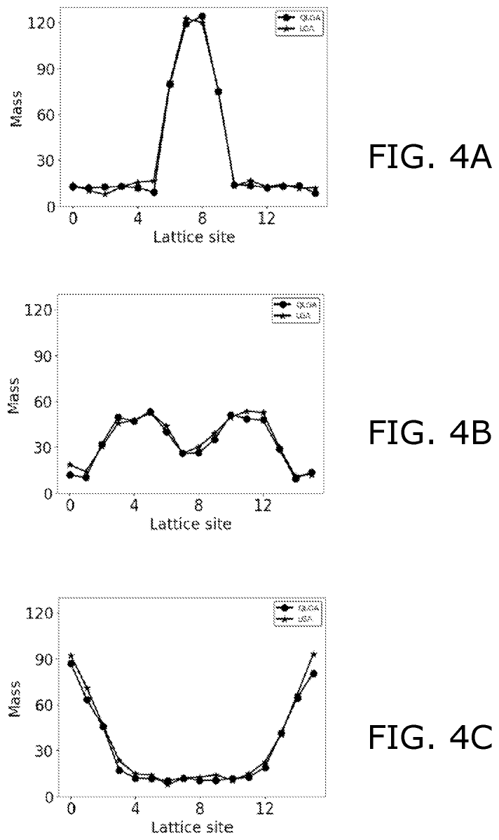

To test the new QLGA model, two benchmarks have been carried out. First, the results of the new QLGA model are compared against a classical version. For this purpose, sub-lattices were used for spatial-averaging. As the initial condition, a sharp profile was set up in the middle of the domain as 95% channel occupancy and 5% of probability for the rest of the model. Several simulations were conducted using the different variants of QLGA, and validated against classical simulations, yielding the same results. One example of these experiments is illustrated in FIGS. 4A, 4B and 4C, wherein the comparison has been made between the classical LGA model and the new QLGA model for different time steps t=0, t=160, t=320, respectively. The simulation was performed using the Aer simulator from Qiskit SDK, without noise, for example, as described in Qiskit contributors, “Qiskit: An open-source framework for quantum computing”, 2023. Besides the sub-lattice averaging, it was found that a statistical ensemble, with different initial conditions for each trial, is necessary to reduce the noise, due to the limited number of qubits in current simulators and quantum computers (more qubits are needed to increase the sub-lattice sites). The results clearly show a diffusion-like behaviour for both of the classical LGA model and the new QLGA model, and the results clearly overlap for each time step. This confirms that the new QLGA model is capable of recreating the behaviour of the classical LGA.

Quantum computing is advancing fast and new devices and architectures with more qubits and less noise are continuously being presented. Noise is unavoidable in quantum devices of today, and it is relevant to find quantum algorithms that can be used under noisy conditions. Therefore, there was also explored how the new QLGA model behaves under different error rates. Due to the high cost of quantum computers and limited access to machines with varying error rates, the new QLGA model was tested with the Qiskit Aer simulator and constructed toy models for the noise. The error rates of the device were manually included. Depolarizing errors are the major contributors to noise in real quantum devices, for example, as also shown in “Simple mitigation of global depolarizing errors in quantum simulations”, by J. Vovrosh et al., published in Phys. Rev. E 104 (2021) 035309. Other variables to consider are the number of shots to extract results, the connectivity of the device, and the set of native gates used. To simplify the analysis as much as possible, the IBM native gate set, which is composed of RZ, X, SX and CX gates, was selected, and the new QLGA model was tested under three noise levels. Each noise model has been created using single-qubit errors, two-qubit errors, a depolarizing error, and a readout error provided by Qiskit.

Table 2 provides the different error rates used for the low, mid, and high noise conditions, as follows:

| | Single Qubit | 2-Qubit | Readout |
|---|---|---|---|
| Noise Level | Error Rate | Error Rate | Error Rate |
| Low | 10⁻⁵ | 10⁻⁴ | 10⁻⁴ |
| Mid (similar | 3 × 10⁻⁵ | 2 × 10⁻³ | 2 × 10⁻³ |
| to Quantinuum | | | |
| H2) | | | |
| High (similar | 6 × 10⁻³ | 2 × 10⁻² | 2 × 10⁻² |
| to early IBM | | | |
| devices) | | | |

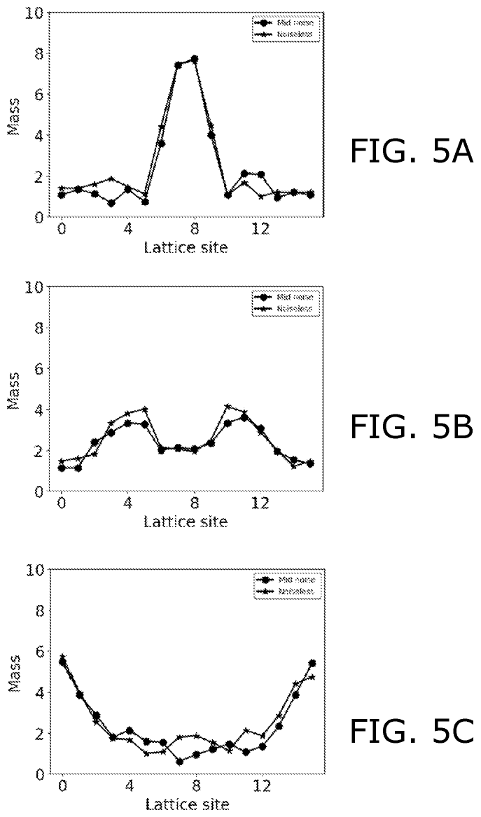

Increasing the number of shots should lead to more accurate simulations. To test this assumption, simulations were run for every noise level with the minimum number of shots required to observe propagation and diffusion up to time step t=24. FIGS. 5A, 5B and 5C show how the simulation behaves in the presence of noise for different time steps t=2, t=16, t=24, respectively. The number of shots was adjusted to the minimum necessary for accurate simulations. An ensemble average of fifteen was used. Additionally, the noiseless simulation was performed with 350 shots, which is found to measure all the states with high probability for this simulation.

The higher the noise, the more shots are required to replicate similar results, as was expected. With increasing noise, it becomes harder to differentiate between the junk states and the desired states in the measurement and post-processing. When the noise is high enough, no valid information can be extracted, and the model freezes or has no propagation using up to 100 k shots. Despite using the IBM native gates here, the simulation with mid-level noise (which includes the same quantum depolarizing error rates from Quantinuum H2 and all-to-all connectivity) indicates that useful simulations could be performed with current quantum computers. These results indicate that while high noise levels make distinguishing between the results and computational junk states challenging, accurate simulations could still be achievable with current noisy devices despite the need for increasing shots.

1. A method of setting up a quantum circuit for a lattice gas automata simulation, the method comprising:
performing an initialization step by setting up, for the quantum circuit, a position register, a channel register and a first ancilla register, wherein the position register comprises a plurality of qubits, the channel register comprises four qubits, and the first ancilla register comprises three ancilla qubits; and
applying to the position register, the channel register and the first ancilla register in a sequential order:
(i) a collision step constructed using a first set of multi-controlled gates, a second set of multi-controlled gates, and four CX gates arranged between the first set and the second set, the collision step being applied to the channel register and the first ancilla register;
(ii) a mapping step constructed using two Hadamard gates and four multi-controlled SWAP gates, the mapping step being applied to the channel register and the first ancilla register; and
(iii) a propagation step being applied to the position register and the first ancilla register.

2. The method according to claim 1, wherein a two-dimensional lattice is represented by a grid of lattice sites, wherein in the initialization step, the qubits of the position register are used to encode positions of the lattice sites in said grid.

3. The method according to claim 1, wherein in the initialization step, the four qubits of the channel register are initialized to encode respective occupancies of four channels per lattice site.

4. The method according to claim 1, wherein in the collision step, the first set of multi-controlled gates comprises in a sequential order:
a first multi-controlled gate that uses a first qubit and a third qubit of the channel register as controls corresponding to a state of |1>, a second qubit and a fourth qubit of the channel register as controls corresponding to a state of |0>, and a first ancilla qubit of the first ancilla register as a target; and
a second multi-controlled gate that uses the first qubit and the third qubit of the channel register as controls corresponding to the state of |0>, the second qubit and the fourth qubit of the channel register as controls corresponding to the state of |1>, and the first ancilla qubit of the first ancilla register as a target;
wherein the four CX gates are arranged after the first set of multi-controlled gates and before the second set of multi-controlled gates, wherein the four CX gates use in a sequential order: the first qubit, the second qubit, the third qubit and the fourth qubit of the channel register as respective targets, each of the four CX gates using the first ancilla qubit of the first ancilla register as a control corresponding to the state of |1>;
wherein the second set of multi-controlled gates comprises in a sequential order:
a third multi-controlled gate that uses the first qubit and the third qubit of the channel register as controls corresponding to the state of |0>, the second qubit and the fourth qubit of the channel register as controls corresponding to the state of |1>, and the first ancilla qubit of the first ancilla register as a target; and
a fourth multi-controlled gate that uses the first qubit and the third qubit of the channel register as controls corresponding to the state of |1>, the second qubit and the fourth qubit of the channel register as controls corresponding to the state of |0>, and the first ancilla qubit of the first ancilla register as a target.

5. The method according to claim 1, wherein in the mapping step, one of the two Hadamard gates is applied to a second ancilla qubit of the first ancilla register, while another of the two Hadamard gates is applied to a third ancilla qubit of the first ancilla register, the two Hadamard gates being applied before the four multi-controlled SWAP gates,
wherein the four multi-controlled SWAP gates comprise in a sequential order:
a first multi-controlled SWAP gate that is applied between a first qubit of the channel register and a first ancilla qubit of the first ancilla register, and that uses the second ancilla qubit of the first ancilla register as a control corresponding to a state of |0> and the third ancilla qubit of the first ancilla register as a control corresponding to a state of |1>;
a second multi-controlled SWAP gate that is applied between a second qubit of the channel register and the first ancilla qubit of the first ancilla register, and that uses the second ancilla qubit of the first ancilla register as a control corresponding to the state of |1> and the third ancilla qubit of the first ancilla register as a control corresponding to the state of |0>;
a third multi-controlled SWAP gate that is applied between a third qubit of the channel register and the first ancilla qubit of the first ancilla register, and that uses the second ancilla qubit and the third ancilla qubit of the first ancilla register as controls corresponding to the state of |1>; and
a fourth multi-controlled SWAP gate that is applied between a fourth qubit of the channel register and the first ancilla qubit of the first ancilla register, and that uses the second ancilla qubit and the third ancilla qubit of the first ancilla register as controls corresponding to the state of |0>.

6. The method according to claim 1, wherein the initialization step is performed using a first equation:
$$\begin{matrix}{{{{{\vert ψ 〉}_{in} = {\hat{I}}_{HPP} \vert ψ 〉}_{0} = {\hat{I}}_{HPP} ( \vert 0 〉}_{l}^{⊗ n} ⊗ \vert 0 〉}_{c}^{⊗ 4} ) ⊗ \vert 0 〉}_{a}^{⊗ 3} \\ {{{{{= \frac{1}{\sqrt{{2}^{n}}} {\sum }_{i = 0}^{{2}^{n} - 1} {d}_{i} ⊗ \vert 0 〉}_{a}^{⊗ 3} = \frac{1}{\sqrt{{2}^{n}}} {\sum }_{i = 0}^{{2}^{n} - 1} \vert {\overbrace{{l}_{1} ... . {l}_{n}}}^{r} \vert {c}_{1} {c}_{2} {c}_{3} {c}_{4} 〉}_{i} ⊗ \vert 0 〉}_{a 1} ⊗ \vert 0 〉}_{a 2} ⊗ \vert 0 〉}_{a 3}\end{matrix}$$
wherein dᵢ represents binary strings that are composed from the qubits of the position register encoding positions of lattice sites and the four qubits of the channel register encoding occupancies of four channels per lattice site.

7. The method according to claim 1, wherein the collision step is applied using a second equation:
$${{{{{{\vert ψ 〉}_{col} = {\hat{C}}_{HPP} \vert ψ 〉}_{in} = \frac{1}{\sqrt{{2}^{n}}} {\sum }_{i} \vert {l}_{1} ... . {l}_{n} \vert {c}_{1}^{′} {c}_{2}^{′} {c}_{3}^{′} {c}_{4}^{′} 〉}_{i} ⊗ \vert 0 〉}_{a}^{⊗ 3} = \frac{1}{\sqrt{{2}^{n}}} {\sum }_{i} \vert {l}_{1} ... . {l}_{n} \vert σ ( {c}_{1} {c}_{2} {c}_{3} {c}_{4} ) 〉}_{i} ⊗ \vert 0 〉}_{a}^{⊗ 3}$$
wherein σ represents a channel map that maps channel states.

8. The method according to claim 7, wherein the channel map maps the channel states according to following collision rules:
a collision between one particle moving down and another particle moving up at a lattice site and represented by a channel state |0101> is mapped to an output in which one particle moves left and another particle moves right as represented by a channel state |1010>;
a collision between one particle moving left and another particle moving right at a lattice site and represented by the channel state |1010> is mapped to an output in which one particle moves up and another particle moves down as represented by the channel state |0101>; and
any other channel state remains unchanged.

9. The method according to claim 1, wherein the mapping step is applied using a third equation:
$$\begin{matrix}{{\vert ψ 〉}_{map} = {\hat{M}}_{HPP} \vert ψ 〉}_{col} \\ {{= {MCSWAP}_{a - c} \frac{1}{\sqrt{{2}^{n}}} {\sum }_{i} \vert {l}_{1} ... . {l}_{n} \vert {c}_{1}^{′} {c}_{2}^{′} {c}_{3}^{′} {c}_{4}^{′} 〉}_{i} ⊗ \vert 0 〉}_{a 1} \\ \\ {{⊗ H \vert 0 〉}_{a2} ⊗ H \vert 0 〉}_{a3} \\ {{= \frac{1}{2 \sqrt{{2}^{n}}} ( {\sum }_{i} \vert {l}_{1} ... . {l}_{n} \vert {c}_{1}^{′} {c}_{2}^{′} {c}_{3}^{′} {a}_{1} 〉}_{i} ⊗ \vert {c}_{4}^{′} 〉 ⊗ \vert 00 〉}_{a 2 , a 3} + \\ {{{\sum }_{i} \vert {l}_{1} ... . {l}_{n} \vert {c}_{1}^{′} {a}_{1} {c}_{3}^{′} {c}_{4}^{′} 〉}_{i} ⊗ \vert {c}_{2}^{′} 〉 ⊗ \vert 10 〉}_{a 2 , a 3} + \\ {{{\sum }_{i} \vert {l}_{1} ... . {l}_{n} \vert {a}_{1} {c}_{2}^{′} {c}_{3}^{′} {c}_{4}^{′} 〉}_{i} ⊗ \vert {c}_{1}^{′} 〉 ⊗ \vert 01 〉}_{a 2 , a 3} + \\ {{{\sum }_{i} \vert {l}_{1} ... . {l}_{n} \vert {c}_{1}^{′} {c}_{2}^{′} {a}_{1} {c}_{4}^{′} 〉}_{i} ⊗ \vert {c}_{3}^{′} 〉 ⊗ \vert 11 〉}_{a 2 , a 3} )\end{matrix} .$$

10. The method according to claim 1, wherein the propagation step is applied using a fourth equation:
$$\begin{matrix}{{{{\vert ψ 〉}_{prop} = {\hat{P}}_{HPP} \vert ψ 〉}_{map} = {\hat{P}}_{HPP} \frac{1}{2 \sqrt{2}} ( {\sum }_{i} \vert {l}_{1} ... . {l}_{n} \vert {c}_{1}^{′} {c}_{2}^{′} {c}_{3}^{′} {a}_{1} 〉}_{i} ⊗ \vert {c}_{4}^{′} 〉 \\ ⊗ \vert 00 〉}_{a 2 , a 3} + \\ {{{\sum }_{i} \vert {l}_{1} ... . {l}_{n} \vert {c}_{1}^{′} {a}_{1} {c}_{3}^{′} {c}_{4}^{′} 〉}_{i} ⊗ \vert {c}_{2}^{′} 〉 ⊗ \vert 10 〉}_{a 2 , a 3} + \\ {{{\sum }_{i} \vert {l}_{1} ... . {l}_{n} \vert {a}_{1} {c}_{2}^{′} {c}_{3}^{′} {c}_{4}^{′} 〉}_{i} ⊗ \vert {c}_{1}^{′} 〉 ⊗ \vert 01 〉}_{a 2 , a 3} + \\ {{{\sum }_{i} \vert {l}_{1} ... . {l}_{n} \vert {c}_{1}^{′} {c}_{2}^{′} {a}_{1} {c}_{4}^{′} 〉}_{i} ⊗ \vert {c}_{3}^{′} 〉 ⊗ \vert 11 〉}_{a 2 , a 3} ) \\ {{{= \frac{1}{2 \sqrt{2}} ( {\sum }_{i} \vert {l}_{1} ... . {l}_{n} 〉}_{i} ⊗ \vert {c}_{1}^{′} {c}_{2}^{′} {c}_{3}^{′} {a}_{1} 〉}_{{π}_{+} ( i )} \\ ⊗ \vert {c}_{4}^{′} 〉 ⊗ \vert 00 〉}_{a 2 , a 3} + \\ {{{{\sum }_{i} \vert {l}_{1} ... . {l}_{n} 〉}_{i} ⊗ \vert {c}_{1}^{′} {a}_{1} {c}_{3}^{′} {c}_{4}^{′} 〉}_{{π}_{-} ( i )} ⊗ \vert {c}_{2}^{′} 〉 ⊗ \vert 10 〉}_{a 2 , a 3} + \\ {{{{\sum }_{i} \vert {l}_{1} ... . {l}_{n} 〉}_{i} ⊗ \vert {a}_{1} {c}_{2}^{′} {c}_{3}^{′} {c}_{4}^{′} 〉}_{{π}_{+ p} ( i )} ⊗ \vert {c}_{1}^{′} 〉 ⊗ \vert 01 〉}_{a 2 , a 3} + \\ {{{{\sum }_{i} \vert {l}_{1} ... . {l}_{n} 〉}_{i} ⊗ \vert {c}_{1}^{′} {c}_{2}^{′} {a}_{1} {c}_{4}^{′} 〉}_{{π}_{- p} ( i )} ⊗ \vert {c}_{3}^{′} 〉 ⊗ \vert 11 〉}_{a 2 , a 3} )\end{matrix}$$
wherein p is equal to a number of lattice sites along a given dimension, wherein π₊(i) and π₋(i) account for periodic single-step shifts in a first dimension as follows:
$${π}_{+} ( i ) = \{ \begin{matrix}i + 1 , & for i ∈ \{ kp , … , ( k + 1 ) p - 2 \} and k ∈ \{ 0 , … , p - 1 \} \\ kp , & for i = ( k + 1 ) p - 1 and k ∈ \{ 0 , … , p - 1 \}\end{matrix}$$
$$and$$
$${π}_{-} ( i ) = \{ \begin{matrix}i - 1 , & for i ∈ \{ kp + 1 , … , ( k + 1 ) p - 1 \} and k ∈ \{ 0 , … , p - 1 \} \\ ( k + 1 ) p - 1 , & for i = kp and k ∈ \{ 0 , … , p - 1 \}\end{matrix}$$
and wherein π₊ₚ(i) and π₋ₚ(i) account for periodic shifts in a second dimension as follows:
$${π}_{+ p} ( i ) = \{ \begin{matrix}i + p , & for i ∈ \{ kp , … , ( k + 1 ) p - 1 \} and k ∈ \{ 0 , … , p - 2 \} \\ i - {p}^{2} + p , & for i ∈ \{ kp , … , ( k + 1 ) p - 1 \} and k = p - 1\end{matrix}$$
$$and$$
$${π}_{- p} ( i ) = \{ \begin{matrix}i - p , & for i ∈ \{ kp , … , ( k + 1 ) p - 1 \} and k ∈ \{ 1 , … , p - 2 \} \\ i + {p}^{2} - p , & for i ∈ \{ kp , … , ( k + 1 ) p - 1 \} and k = 0\end{matrix} .$$

11. The method according to claim 1, wherein the quantum circuit, after set up, is used for performing the lattice gas automata simulation.

12. A quantum computer or a quantum emulator configured to execute a method according to claim 1.

13. The quantum computer or the quantum emulator according to claim 12, wherein the quantum computer or the quantum emulator is used to perform a lattice gas automata simulation.

14. A computer program product having computer program instructions stored thereon, the computer program instructions being executable by at least one processor in a classical computer to control a quantum computer or a quantum emulator to perform a method according to claim 1.
